(19) United States
(12) Patent Application Publication
(10) Pub. No.: US 2026/0276469 A1
(43) Pub. Date: Sep. 17, 2026

(54) METHOD, DEVICE, AND APPLICATION THEREOF FOR MEASURING GAS INSIDE A FOUP

(71) Applicant: ASIA NEO TECH INDUSTRIAL CO., LTD., TAOYUAN CITY (TW)

(72) Inventor: PU-CHANG YEH, TAOYUAN CITY (TW)

(21) Appl. No.: 19/290,657

(22) Filed: Aug. 5, 2025

(30) Foreign Application Priority Data
Mar. 12, 2025 (TW) 114109085

(51) Int. Cl. G01M 3/04; H01L 21/673

(52) U.S. Cl. CPC G01M 3/04; H10P 72/1924

(57) ABSTRACT

The present invention provides a method, device, and application thereof for measuring gas inside a FOUP. The method comprises: constructing a closed gas loop via at least two valve ports connected to a compartment space of the FOUP; driving the gas to generate an internal circulation flow between the gas loop and the compartment space; and measuring the content of a judgment factor in the circulating gas to evaluate the air-tightness of the compartment space. The invention also provides a measuring device for gas in the FOUP, and the measuring method and device can also be used for detecting the humidity in the compartment space.

### BACKGROUND OF INVENTION

### 1. Field of the Invention

The present invention relates to a transfer pod for storing materials, wherein the materials may be one of a semiconductor wafer, an electronic carrier board, or a circuit substrate. The invention is particularly directed to a method, device, and application thereof for measuring gas inside a FOUP.

### 2. Description of Related Art

Currently, on the production lines of materials such as semiconductor chips, electronic carrier boards, and circuit substrates, a front-opening unified pod (FOUP) is used to hold these materials. The FOUP is hung and transported by an overhead hoist transport (OHT) to various process stations for the processing of the materials. The interior of the FOUP has a compartment space for accommodating the materials. This compartment space must have a certain level of cleanliness and dryness. In addition, according to the requirements of some processes, the compartment space also needs to be filled with a certain concentration of process gases [such as nitrogen (N2), extra clean dry air (XCDA), etc.]. Therefore, the air-tightness of the compartment space from the outside has been strictly required by the industry to maintain the processing quality of the materials inside.

Please refer to FIG. 1a to FIG. 1e together. FIG. 1a shows the structure of the conventional FOUP 10, indicating that the FOUP 10 is formed by locking a door 12 to a hollow shell 11. FIG. 1b shows that the door 12 can be unlocked and separated from the shell 11 to open the opening 16 of the shell 11 to expose the internal compartment space 14, so that the materials can be placed in the compartment space 14. Moreover, an airtight seal ring 121 is provided on the periphery of the inner surface of the door 12 to prevent gas leakage after the door 12 and the shell 11 are locked. In addition, one side of the shell 11 has a seat portion 13, and the bottom surface of the seat portion 13 is flat. FIG. 1c further shows that the bottom surface of the seat portion 13 has a plurality of valve ports 15 that can be connected to the compartment space 14 when needed for filling the process gases. Each valve port 15 includes a pair of gas inlet valve ports 151 and a pair of gas outlet valve ports 152. In addition, FIG. 1d and FIG. 1e also show that the gas inlet valve port 151 and the gas outlet valve port 152 are respectively composed of one-way check valves that can control the direction of the gas flow. The solid arrows indicate the directions in which the gas can push open the valves. As shown, the valve-opening directions of the gas inlet valve port 151 and the gas outlet valve port 152 are opposite. Specifically, the one-way check valve of the gas inlet valve port 151 (as shown in FIG. 1d) can control the gas only to enter the compartment space 14 of the FOUP 10 from the outside, and the one-way check valve of the gas outlet valve port 152 (as shown in FIG. 1e) can control the gas only to be discharged from the compartment space 14 of the FOUP 10 to the outside.

The above-mentioned gas inlet valve port 151 can be pushed open by the pressure of a gas from a gas supply pipeline or be pushed open by a protruding nozzle on the gas supply pipeline. The above-mentioned gas outlet valve port 152 needs to be opened by the internal pressure of the gas accumulated in the compartment space 14. Although the above-mentioned valve ports 15 all have the function of allowing gas flow in one direction only to prevent gas from entering or exiting the compartment space 14, and the airtight seal ring 121 of the door 12 also has the function of sealing the opening 16 (as shown in FIG. 1b), over time, these valve ports 15 may have their gas-blocking effects affected due to factors such as the aging of the one-way check valves or poor assembly quality, and the airtight seal ring 121 on the door 12 may also have its air-tightness affected due to factors such as aging or poor assembly quality. In addition, after a long time of opening and closing operations, these valve ports 15 and the door 12 will also have their gas-blocking or air-tightness affected.

It is known that once the gas-blocking or air-tightness of the above-mentioned valve ports 15 and the door 12 is poor, the gas inside the compartment space 14 can leak to the outside through these valve ports 15 and the opening 16. At the same time, the unfiltered dirty air and moisture from the outside can also flow into the compartment space 14 through these valve ports 15 and the opening 16, thereby affecting the cleanliness and dryness of the compartment space 14.

In order to overcome the problem of poor air-tightness of the compartment space 14 of the FOUP 10, manufactures often need to examine the air-tightness of the compartment space 14 of the FOUP 10 and stop using the FOUPs 10 with poor air-tightness.

Patent US20200051844A1 disclosed a technique for detecting air-tightness of FOUPs. According to this patent, a measuring pipeline is connected to at least one of the gas inlet valve ports 151 of the above-mentioned FOUP 10. A protruding nozzle for opening the gas inlet valve port 151 is configured on the measuring pipeline, and a flow controller or a pressure sensor is also connected in series on the measuring pipeline. When the measuring pipeline is filled with gas and the gas is guided into the compartment space 14, the gas filling can be automatically stopped, so that the gas in the interconnected measuring pipeline and the compartment space 14 is maintained at a specific internal pressure. Then, within a specific time, the flow controller or the pressure sensor is used to measure the leakage flow of the gas in the measuring pipeline and the compartment space 14, or to measure the internal pressure of the remaining gas, so as to detect the air-tightness of the compartment space 14 of the FOUP 10.

However, the air-tightness detection method of Patent US20200051844A1 can only measure the gas leakage or pressure drop, and can at best only obtain an estimated pressure value of the remaining gas in the compartment space 14. It cannot tell whether the concentration and dryness (or humidity) of the gas remaining in the compartment space 14 still meet the standard. This is a shortcoming to be improved.

### SUMMARY OF THE INVENTION

The present invention will take the FOUP 10 shown in FIG. 1a to FIG. 1e as an example to illustrate a method to measure the gas filled inside the FOUP 10. This method can be used for detecting the air-tightness of the FOUP 10 and simultaneously detecting the concentration and humidity of the gas inside the FOUP 10.

The method for measuring gas inside a FOUP comprises: constructing a closed gas loop, which is connected to the compartment space via at least two valve ports; generating an internal circulating flow of the gas between the compartment space and the gas loop; and measuring the content of a judgment factor in the circulating gas to evaluate the air-tightness of the compartment space and the gas concentration.

In a further embodiment, before generating an internal circulating flow of the gas, the gas may first be filled into the compartment space via the gas loop. Alternatively, the gas may be filled into the gas loop before connecting it to the compartment space.

In a further embodiment, the gas may be nitrogen, an inert gas, or air. When nitrogen is used, the judgment factor is the oxygen or nitrogen content in the nitrogen gas. When an inert gas is used, the judgment factor is the content of oxygen, helium, neon, argon, krypton, xenon, or radon. When air is used, the judgment factor is the oxygen content in the air. Said air may include ultra-clean dry air.

In a further embodiment, the gas method further includes detecting humidity within the compartment space, where the judgment factor is the water molecule content in the gas.

The present invention also provides a gas measuring device for implementing the aforementioned method. The device comprises: a gas driver and a detecting element in serial connection to a gas delivery pipe. The gas delivery pipe connects at least two valve ports and communicates with the compartment space to direct the gas into the compartment space to form a closed gas loop. The gas driver is used to generate an internal circulating flow of the gas between the compartment space and the gas delivery pipe. The detecting element, serially connected to the gas delivery pipe and positioned between the gas driver 30 and at least one of the two valve ports, is used to measure the content of the judgment factor in the circulating gas.

In a further embodiment, the at least two valve ports include two gas inlet valve ports. The two ends of the gas delivery pipe are respectively connected to a disk-shaped connector. At least one of the disk-shaped connectors has a protruding nozzle. The gas delivery pipe seals the two valve ports via the two disk-shaped connectors and is inserted into at least one of the gas inlet valve ports via the protruding nozzle. In this way, the gas delivery pipe is communicated with the compartment space.

In another embodiment, the at least two valve ports include at least one gas inlet valve port and at least one gas outlet valve port. The two ends of the gas delivery pipe are connected to at least one disk-shaped connector. The gas delivery pipe seals the at least one gas inlet valve port and the at least one gas outlet valve port via a plurality of disk-shaped connectors. In this way, the gas delivery pipe is communicated with the compartment space. At least one of the plurality of disk-shaped connectors may be implemented in a shape having a protruding nozzle, so that the gas delivery pipe can be inserted into at least one of the gas inlet valve ports via at least one of the protruding nozzle.

In a further embodiment, the measuring device may be mounted on a platform for placing the FOUP, with the disk-shaped connectors protruding from the platform to allow plug-in connection with the valve ports when the FOUP is placed, so as to connect with the gas delivery pipe.

In a further embodiment, the gas delivery pipe may extend to form at least one gas inlet manifold pipe that is communicated with a gas supply and at least one gas outlet manifold pipe for discharging the gas. A plurality of switches are configured on the gas delivery pipe, the gas inlet manifold pipe, and the gas outlet manifold pipe to control the time for filling, directing, and discharging the gas. The plurality of switches may respectively be made of a solenoid valve.

In a further embodiment, the gas driver is a pump or a blower.

In a further embodiment, when the gas is nitrogen, and the judgment factor is the oxygen or nitrogen content in the nitrogen gas, the detecting element is an oxygen sensor or a gas monitoring instrument that can detect nitrogen content.

When the gas is an inert gas and the judgment factor is oxygen, helium, neon, argon, krypton, xenon, or radon, the detecting element is an oxygen sensor or a gas monitoring instrument that can detect the content of oxygen, helium, neon, argon, krypton, xenon, or radon.

When the gas is air and the judgment factor is oxygen content in the air, the detecting element is an oxygen sensor.

When used for detecting humidity in the compartment space, and the judgement factor is content of water molecules in the gas, the detecting element is a moisture sensor.

Based on the above contents, the invention can realize the following effects:
1. It can detect the gas concentration and humidity in the compartment space while detecting the air-tightness of the FOUP, thereby fully maintaining the process quality of the internally loaded materials.
2. The air-tightness detection of the FOUP can be carried out according to the type and concentration of the gas required in the process. Moreover, when the concentration of the gas used in the internal circulation is higher, the air-tightness of the FOUP can be detected more accurately.
3. By virtue of the gas loop for the internal circulating flow of the gas, substances that can affect cleanliness and dryness, including water molecules, other dirt or particles, can be carried away from the compartment space.

Further benefits and advantages of the present invention will become apparent after a careful reading of the detailed description with appropriate reference to the accompanying drawings.

### BRIEF DESCRIPTION OF THE DRAWINGS

FIG. 1a is a perspective view of a prior-art FOUP.

FIG. 1b is an exploded perspective view of the FOUP shown in FIG. 1a.

FIG. 1c is a bottom view of the FOUP shown in FIG. 1a, revealing the configuration details of the gas inlet valve port and the gas outlet valve port.

FIG. 1d is a sectional view of the gas inlet valve port shown in FIG. 1c.

FIG. 1e is a sectional view of the gas outlet valve port shown in FIG. 1c.

FIG. 2 is a step-by-step flowchart of the first measuring method of the present invention.

FIG. 3 is an explanatory diagram of a configuration of the measuring method shown in FIG. 2, revealing an implementation mode in which the gas inlet valve port of the FOUP is connected to a closed gas loop.

FIG. 4a is an explanatory sectional diagram of one way the gas inlet valve port shown in FIG. 3 and FIG. 5 provides connection for the gas loop.

FIG. 4b is an explanatory sectional diagram of another way the gas inlet valve port shown in FIG. 3 and FIG. 5 provides connection for the gas loop.

FIG. 5 is an explanatory diagram of another configuration of the measuring method shown in FIG. 2, revealing an implementation mode in which the gas inlet valve port and the gas outlet valve port of the FOUP are connected to a closed gas loop.

FIG. 6 is an explanatory sectional diagram of the gas outlet valve port shown in FIG. 5 providing connection for the gas loop.

FIG. 7 is a step-by-step flowchart of the second-type measuring method of the present invention.

FIG. 8 is a step-by-step flowchart of the third-type measuring method of the present invention.

FIG. 9a is a schematic diagram of the configuration of the first measuring device of the present invention, further revealing the design of the device to execute the measurement technique shown in FIG. 3.

FIG. 9b is an explanatory diagram of the first type of operation of the configuration shown in FIG. 9a, further revealing the implementation modes of Step S20 to Step S30 shown in FIG. 2 and FIG. 7, and Step S13 to Step S30 shown in FIG. 8.

FIG. 9c is an explanatory diagram of the second type of operation of the configuration shown in FIG. 9a, further revealing the implementation mode of Step S11 in FIG. 7 to fill gas into the compartment space.

FIG. 9d is an explanatory diagram of the third type of operation of the configuration shown in FIG. 9a, further revealing the implementation mode of Step S12 in FIG. 8 to fill gas into the gas loop.

FIG. 10a is a schematic diagram of the configuration of the second-type measuring device of the present invention, further revealing the design of the device to execute the measurement technique shown in FIG. 5.

FIG. 10b is an explanatory diagram of the first type of operation of the configuration shown in FIG. 10a, further revealing the implementation modes of Step S20 to Step S30 shown in FIG. 2 and FIG. 7, and Step S13 to Step S30 shown in FIG. 8.

FIG. 10c is an explanatory diagram of the second type of operation of the configuration shown in FIG. 10a, further revealing the implementation mode of Step S11 shown in FIG. 7 to fill gas into the compartment space.

FIG. 10d is an explanatory diagram of the third type of operation of the configuration shown in FIG. 10a, further revealing the implementation mode of Step S12 shown in FIG. 8 to fill gas into the gas loop.

FIG. 11 is a partial sectional view of the measuring device shown in FIG. 10a constructed on the tabletop of a working machine.

### DETAILED DESCRIPTION OF THE INVENTION

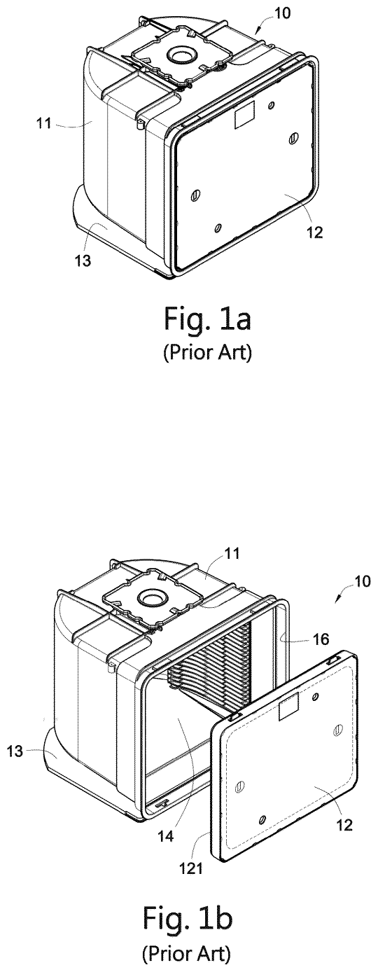

In the following content of the present invention, the FOUP 10 shown in FIG. 1a to FIG. 1d is used as an example to demonstrate that, after the door 12 of the FOUP 10 is locked to the opening 16 of the shell 11 to produce an air-stopping effect, the air-tightness of the compartment space 14 and the concentration of the internal gas can be detected by the measuring method to be described later in the present invention.

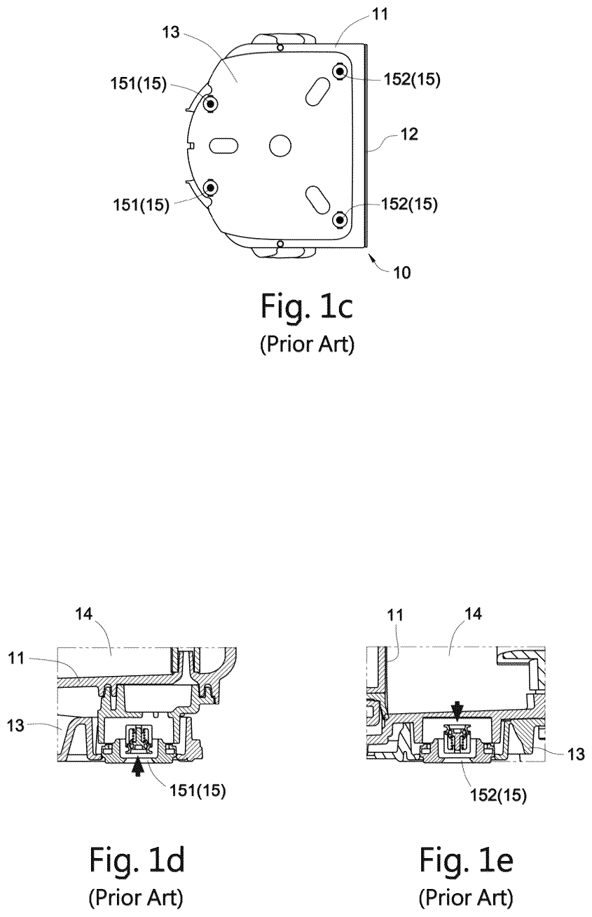

First, please refer to FIG. 2, which discloses the execution procedure of the first measuring method of the present invention, including sequentially executing the following Step S10 to Step S30, where:

### Step S10: Constructing a Gas Loop

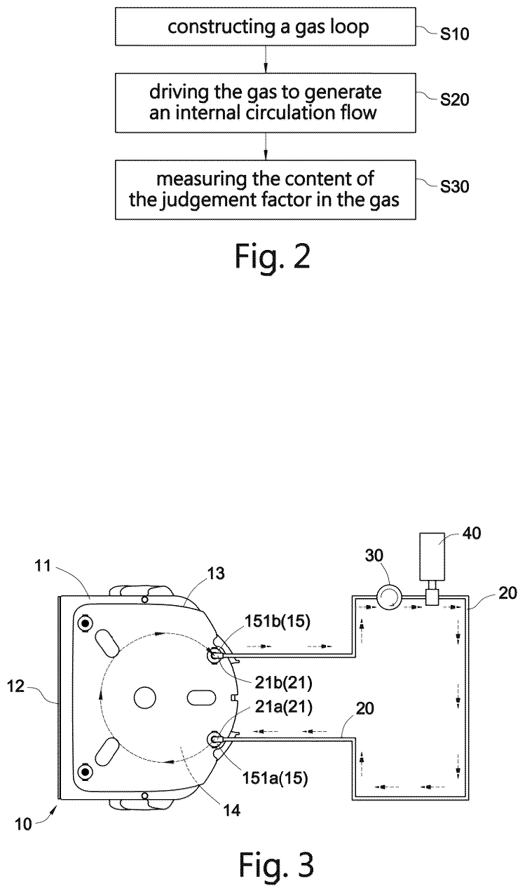

Please refer to FIG. 3, which discloses the first configuration type of the gas loop 20. It is explained that in this step, a closed gas loop 20 for guiding gas is constructed between a pair of gas inlet valve ports 151a, 151b of the shell 11. The gas loop 20 can be a pipeline formed by means of serial connection or serial and parallel connection of soft or hard gas delivery pipes (to be detailed later). Both ends of the gas loop 20 are respectively provided with a disk-shaped connector 21. The gas loop 20 can be connected to the pair of gas inlet valve ports 151a, 151b through the disk-shaped connectors 21 at both ends.

In this example, one of the two gas inlet valve ports 151a, 151b (for example, the gas inlet valve port 151b shown in FIG. 3) must be forcibly used as a gas outlet port to specifically construct the gas loop 20.

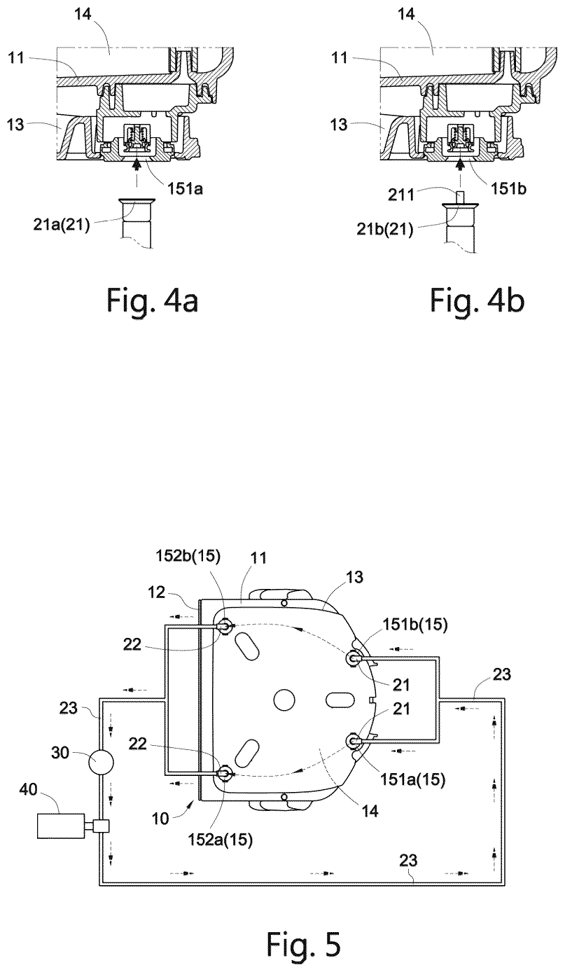

Based on this, please continue to refer to FIG. 4a and FIG. 4b, which disclose that the two disk-shaped connectors 21 must be distinguished into a disk-shaped connector 21a without the protruding nozzle 211 (as shown in FIG. 4a) and a disk-shaped connector 21b with the protruding nozzle 211 (as shown in FIG. 4b). Among them, the disk-shaped connector 21a without the protruding nozzle 211 is connected to the gas inlet valve port 151a (as shown in FIG. 4a), and is used to naturally push open the one-way check valve in the gas inlet valve port 151a by virtue of the gas supply pressure in the gas loop 20, so that the gas inlet valve port 151a can serve as a gas inlet port for supplying gas into the compartment space 14. The disk-shaped connector 21b with the protruding nozzle 211 is connected to the gas inlet valve port 151b (as shown in FIG. 4a), and the one-way check valve in the gas inlet valve port 151b is forcibly pushed open by virtue of the protruding nozzle 211, so that the gas inlet valve port 151b can serve as a gas outlet port of the compartment space 14. In this way, the gas loop 20 can communicate with the compartment space 14. The dotted arrow in FIG. 3 indicates the path and direction of the internal circulation flow of the gas in the gas loop 20.

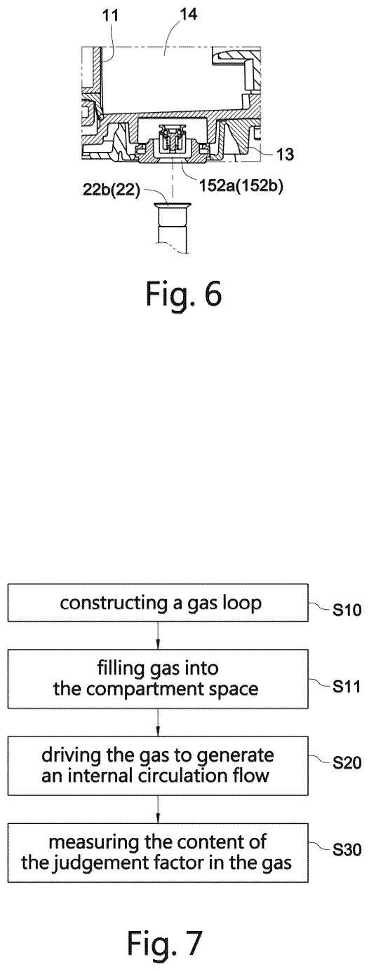

Please refer to FIG. 5, which discloses an embodiment diagram of the second-type of the gas loop 23. It is explained that both ends of the gas loop 23 are respectively provided with a pair of disk-shaped connectors 21, 22 of two different types for respectively connecting to the paired gas inlet valve ports 151a, 151b and the paired gas outlet valve ports 152a, 152b. Further, the difference between the embodiment shown in FIG. 5 and the embodiment shown in FIG. 3 lies in:

The disk-shaped connectors 21 used for connecting the gas inlet valve ports 151a, 151b, depending on the current situation of the equipment end, can be the disk-shaped connector 21b without the protruding nozzle 211 as shown in FIG. 4b, or the disk-shaped connector 21a with the protruding nozzle 211 as shown in FIG. 4b.

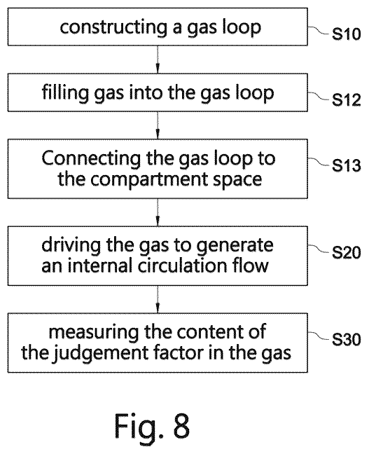

In addition, please refer to FIG. 6, which discloses that the disk-shaped connector 22 used for connecting the gas outlet valve ports 152a, 152b is a disk-shaped connector 22b without the protruding nozzle 211.

Accordingly, both ends of the gas loop 23 can communicate with the compartment space 14 through the disk-shaped connectors 21, 22. In FIG. 5, the dashed arrows indicate the path and direction of the internal circulation flow of the gas in the gas loop 20.

In addition, both ends of the gas loop 23 only need to be respectively provided with a single disk-shaped connector 21, 22, and be respectively connected to a single gas inlet valve port 151a (or 151b) and a single gas outlet valve port 152a (or 152b) to produce the same effect of communicating with the compartment space 14.

Here, it must be noted that, before the gas loop 23 and the interior of the compartment space 14 are connected, there is already gas (hereinafter referred to as the original gas), such as air or nitrogen, stored inside them. And after the gas loop 23 and the compartment space 14 are connected to each other, the original gas (such as air or nitrogen) can naturally flow between the gas loop 23 and the compartment space 14. In addition, the original gas can also circulate in the gas loop 23 along with the gas filled from the outside into the compartment space 14 (hereinafter referred to as filling gas).

### Step S20: Driving the Gas to Generate an Internal Circulation Flow

Referring to FIG. 3 and FIG. 5 again, this step utilizes a gas driver 30 connected in series on the gas loops 20, 23. The gas driver 30 is made of a pump that can agitate the gas to generate a flow rate, or made of a blower, which is used to drive the gas (including at least one of the original gas and the filling gas) in the gas loops 20, 23 and the compartment space 14 to generate an internal circulation flow between the compartment space 14 and the gas loops 20, 23 (the flow direction of the gas is indicated by the dotted arrow in the figure), so that at least one of the original gas and the filling gas is transformed into a gas to be measured. The transformation means mixture due to the circulation flow.

FIG. 3 also reveals that the original gas or filling gas in the gas loop 20 can enter the compartment space 14 through one of the two gas inlet valve ports 151a, 151b (e.g., 151a), and the original gas or filling gas in the compartment space 14 can flow back into the gas loop 20 through the other one of the two gas inlet valve ports 151a, 151b (e.g., 151b), thus generating the internal circulation flow of the gas to be measured. FIG. 5 reveals that the original gas or filling gas in the gas loop 23 can enter the compartment space 14 through the two gas inlet valve ports 151a, 151b, and the original gas or filling gas in the compartment space 14 can flow back into the gas loop 23 through the two gas outlet valve ports 152a, 152b, thus generating the internal circulation flow of the gas to be measured.

### Step S30: Measuring the Content of the Judgement Factor in the Gas

Please refer to FIG. 3 and FIG. 5 again. This step utilizes a detecting element 40 connected in series on the gas loops 20, 23 (i.e., the gas delivery pipe). The detecting element 40 can be connected between the gas inlet valve port 151b and the gas driver 30 at the gas outlet end (as shown in FIG. 3). The detecting element 40 can also be connected between the two gas outlet valve ports 152a, 152b (or one of the gas outlet valve ports 152a or 152b) and the gas driver 30 at the gas outlet end (as shown in FIG. 5). Thus, the detecting element 40 can be used to measure the content of a judgement factor in the gas to be measured in the internal circulation flow at the beginning of the agitation to generate the gas internal circulation flow in Step S20 or after an execution time (to be detailed later).

When the gas to be measured is air, an oxygen sensor (O2 Sensor) can be selected as the detecting element 40, and the judgement factor is the oxygen content in the air. When the gas to be measured is nitrogen, the oxygen sensor or a gas monitoring instrument capable of detecting the nitrogen content can be selected as the detecting element 40, and the judgement factor is the oxygen content or nitrogen content in the nitrogen.

During the measurement period, when the content of the judgement factor in the gas to be measured decreases, and the decreasing amplitude exceeds the specification standard set by the quality control end, it means that the air-tightness of the FOUP 10 is poor. That is to say, the leakage of the nitrogen (i.e., the gas to be measured) in the compartment space 14 through the opening 16 or any of the valve ports 15 has exceeded the standard set by the quality control end, and the FOUP 10 should be regarded as a defective product and be removed from the production line of the manufacturing process. Moreover, through the measurement of the content of the judgement factor in the gas to be measured, the concentration of the gas to be measured can also be determined to maintain the process quality of the internal materials.

In addition, the gas to be measured can also be an inert gas or ultra-clean dry air commonly used in the process, or even the air in the atmospheric environment. When the gas to be measured is an inert gas, the detecting element 40 adopts the above-mentioned oxygen sensor, or a gas monitoring instrument capable of detecting the content of helium, neon, argon, krypton, xenon or radon, and the judgement factor is one of oxygen, helium, neon, argon, krypton, xenon, and radon. It must be noted that the original gas in the gas loop 23 and the compartment space 14 can be the same or different gases, and they can all be mixed into the gas to be measured containing the judgement factor. This will not affect the execution of the above Step S10 to Step S30.

### Step S11: Filling Gas Into the Compartment Space

Please refer to FIG. 3 and FIG. 5 again. It is disclosed that, in this step, the gas guide channel (to be detailed later) connected to one side of the gas loops 20, 23 can provide a sufficient amount of the filling gas with a considerable concentration. The filling gas enters the compartment space 14 through the gas loops 20, 23 to form a positive pressure. Here, the positive pressure means that the gas pressure in the gas loops 20, 23 and the compartment space 14 is greater than the atmospheric pressure (1 atm).

In this step, the filling gas can be the same as or different from the original gas in the aforementioned step S20, and both can be mixed with each other to become the gas to be measured in the aforementioned step S30. Further, the filling gas can be selected according to the requirements of the materials accommodated in the FOUP 10 or the process requirements. For example, the filling gas can be one of the aforementioned nitrogen (N2), air, or inert gases. Said air includes the known ultra-clean dry air (XCDA).

In the process from the above Step S11 to step S30, taking nitrogen (N2) as the filling gas and 360 seconds as the execution time as an example, it is explained that, before the execution of Step S11 (before 0 second), if the original gas in the gas loops 20, 23 and the compartment space 14 is air, in Step S11, nitrogen with a concentration of 99.99% is used as the filling gas, and the nitrogen filling stops after the period from the 0th second to the 120th second, so that the concentration of the filled nitrogen (99.99%) is higher than the nitrogen content or nitrogen concentration in the natural air (79%). After standing from the 121st second to the 160th second, the original gas (such as air) can be fully mixed with the filling gas (nitrogen with a concentration of 99%) to form the gas to be measured (such as nitrogen with a concentration of 80%). Then, in step S20, the nitrogen is agitated to generate a closed-loop internal circulation flow from the 161st second to the 170th second. Subsequently, from the 171st second to the 360th second, step S30 is carried out, i.e., the detecting element 40 executes the measurement. In addition, step S30 for executing the measurement by the detecting element 40 can also be carried out at any time point from the start of Step S11 when the filling gas enters the compartment space 14 to the end of step S20 when the internal circulation of the gas is agitated (that is, the 170th second). This can help increase the amount of measurement data of the judgment factor or shorten the aforementioned execution time of 360 seconds.

Specifically, the detecting element 40 can be an oxygen sensor (O2 Sensor) or a gas monitoring instrument capable of detecting the nitrogen content, so that the detecting element 40 can detect the oxygen content or nitrogen content in the nitrogen with a concentration of 80% in the internal circulation flow as the judgment factor.

In particular, if the oxygen content or nitrogen content of the gas to be measured decreases during the measurement period, and the decreasing amplitude exceeds the standard set by the quality control end, it means that the air-tightness of the FOUP 10 is poor. This indicates that the leakage of the nitrogen with a concentration of 80% (i.e., the gas to be measured) in the compartment space 14 through the opening 16 or any of the valve ports 15 has exceeded the standard set by the quality control end and the FOUP 10 should be regarded as a defective product and be removed from the production line of the manufacturing process.

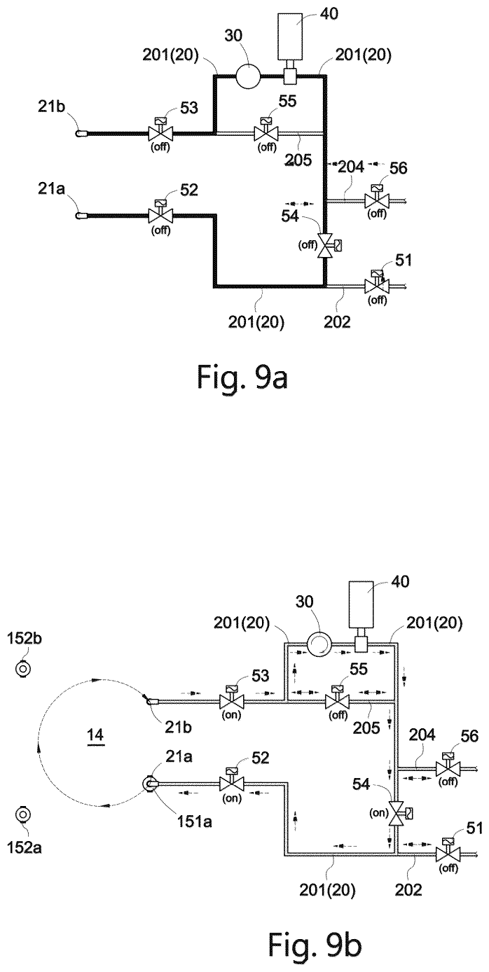

Accordingly, in the detection procedure shown in FIG. 7, the concentration of the gas in the gas loops 20, 23 can be increased by filling additional gas from the outside. It is to be understood that the higher the concentration of the gas used in the internal circulation, the more accurately the air-tightness of the FOUP can be detected.

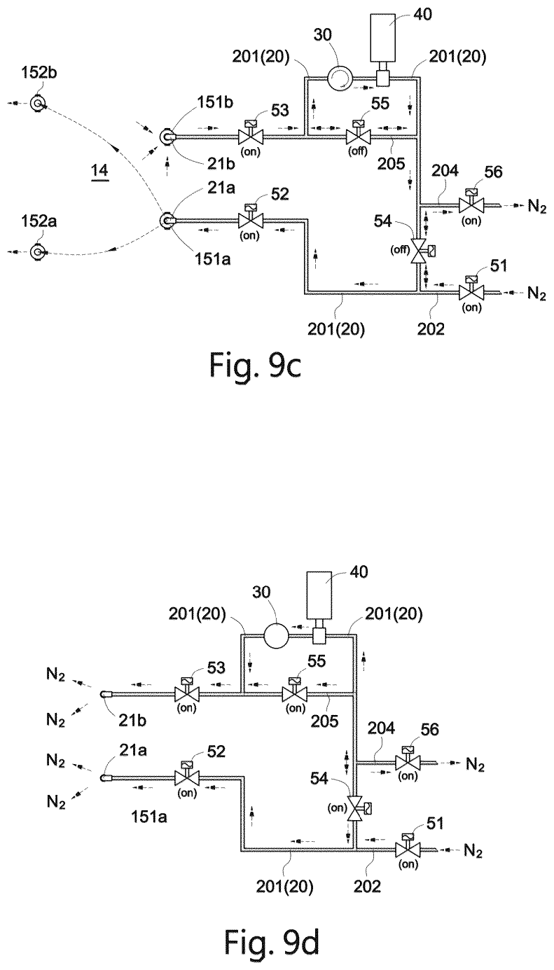

Next, please refer to FIG. 8, which discloses the execution procedure of the third-type measuring method of the present invention. After the execution of the aforementioned Step S10 and before the execution of step S20 (as shown in FIG. 2), the following steps S12 to S13 are additionally carried out in sequence.

### Step S12: Filling Gas Into the Gas Loop

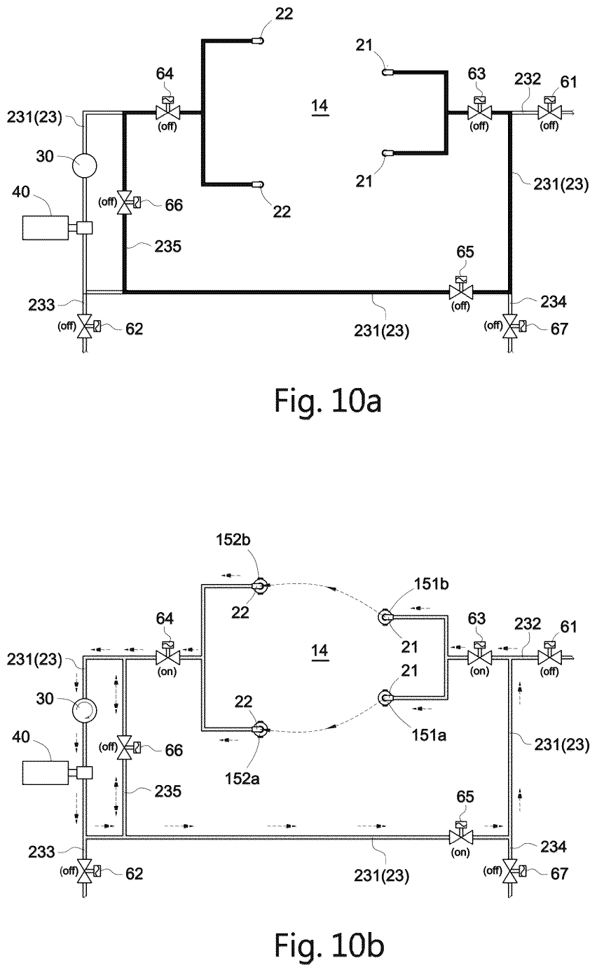

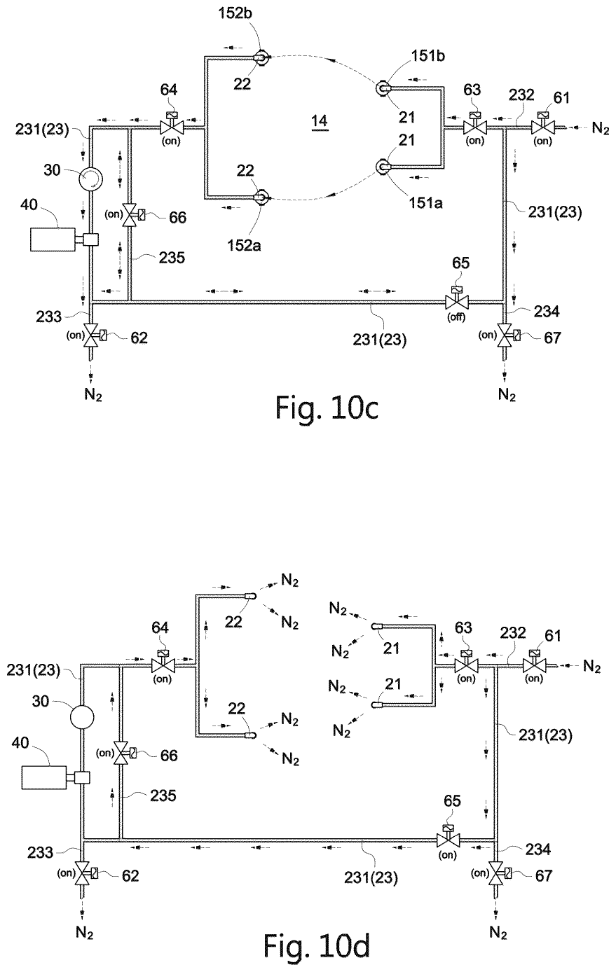

Please refer to FIG. 9a and FIG. 10a in advance, which respectively disclose the arrangement of two types of gas loops. As shown, the gas loops 20, 23 constructed in Step S10 are not yet connected to the valve port 15 of the FOUP 10. Now, perform this Step S12 to fill gas into the gas loops 20, 23.

The difference between this Step S12 and the aforementioned Step S11 is that in Step S11, the gas loops 20, 23 are already connected to the valve port 15 of the FOUP 10 to fill gas into the compartment space 14, while in this Step S12, the filling gas is filled in the state where the gas loops 20, 23 are not yet connected to the valve port 15. In this way, the filling gas can gather in the gas loops 20, 23 in advance to generate a positive pressure. Other details are the same as the content described in the aforementioned Step S11.

### Step S13: Connecting the Gas Loop to the Compartment Space

The purpose of this Step is: after the gas loops 20, 23 are filled with the filling gas with positive pressure, connect the gas loops 20, 23 to the valve ports 15 of the FOUP 10 according to the aforementioned implementation method, so that the filling gas with positive pressure in the gas loops 20, 23 can be quickly filled into the compartment space for pressure maintenance. This will facilitate the subsequent implementation of the aforementioned agitation of the gas to generate internal circulation flow (i.e., Step S20) and the measurement of the content of the judgement factor in the gas to be measured (Step S30).

Accordingly, in the detection procedure shown in FIG. 8, the gas loops 20, 23 can be filled with sufficient gas in advance, without waiting to be connected to the FOUP 10 before implementing gas filling. Therefore, it has the effect of accelerating the measurement procedure.

Furthermore, the present invention also includes the application of the aforementioned method for measuring various internal circulation gases to detect the humidity in the compartment space 14 of the FOUP 10. Now, the judgment factor is the water molecule content in the gas, and the detecting element 40 must be replaced with a moisture sensor capable of detecting the water molecule content in the gas. The moisture sensor is used to detect the humidity in the compartment space 14 of the cleaned FOUP 10, so as to control the dryness in the compartment space 14 to meet the standards set by the quality control end. Other details are the same as the implementation content of the above multiple types of measuring methods.

In addition, in order to implement the above detection method, please continue to refer to FIG. 9a, which discloses a schematic configuration diagram of the first measuring device of the present invention, used to illustrate the design of the device to execute the measurement technique shown in FIG. 3, especially including the implementation details of establishing the gas loop in the aforementioned Step 10.

As shown in FIG. 9a, the measuring device includes a gas delivery pipe 201 for serial connection with the gas driver 30 and the detecting element 40. Therefore, the gas loop 20 shown in FIG. 3 is formed by serially connecting the gas delivery pipe 201 with the gas driver 30 and the detecting element 40 in different sections. The gas delivery pipe 201 shown as a solid line in FIG. 9a constitutes the gas loop 20 shown in FIG. 3, and the two disk-shaped connectors 21a, 21b are installed at both ends of the gas delivery pipe 201, so that, when measurement is needed, they can be correspondingly connected to the two gas inlet valve ports 151a, 151b of the FOUP 10. Based on this configuration, the detecting element 40 can be serially connected on the gas delivery pipe 201 and be located between the gas driver 30 and any one of the two gas inlet valve ports 151a, 151b.

FIG. 9a also discloses that a gas inlet manifold pipe 202 capable of connecting to the gas supply end and a discharge pipe 204 are branched on the gas delivery pipe 201, and a communicating pipe 205 can be connected in parallel between the gas driver 30 and the gas delivery pipe 201 located on both sides of the detecting element 40.

In addition, a plurality of switches 51~56 are arranged at intervals on the gas delivery pipe 201, and the plurality of said switches can be made of solenoid valves or other electric or manual switches. In FIG. 9a, solenoid valves are used as the said switches. As shown, the plurality of said switches may include a first switch 51 connected in series to the gas inlet manifold pipe 202, a second switch 52 connected in series to the inlet end of the gas delivery pipe 201 adjacent to the disk-shaped connector 21a, a third switch 53 connected in series to the gas delivery pipe 201 between the disk-shaped connector 21a and the gas driver 30, a fourth switch 54 connected in series to the gas delivery pipe 201 between the detecting element 40 and the second switch 52, a fifth switch 55 connected in series to the communicating pipe 205, and a sixth switch 56 connected in series to the discharge pipe 204. As depicted in FIG. 9a, when the plurality of said switches 51~56 are all closed (off), the measuring device is in a standby state.

FIG. 9b is an explanatory diagram of the first type of operation of the configuration shown in FIG. 9a, further revealing the implementation modes of Step S20 to Step S30 shown in FIG. 2.

As shown in FIG. 9b, the gas loop 20 constructed and formed in FIG. 9a can be connected to the gas inlet valve ports 151a, 151b of the FOUP 10 shown in FIG. 3 through the said disk-shaped connectors 21a, 21b at both ends of the gas delivery pipe 201. Subsequently, the second switch 52, the third switch 53, and the fourth switch 54 are opened (on), and the first switch 51, the fifth switch 55, and the sixth switch 56 remain closed (off). At this time, the original gas in the gas delivery pipe 201 can be agitated by the gas driver 30, and is introduced into the compartment space 14 through the gas inlet valve port 151a, and is mixed with the original gas in the compartment space 14, and then discharged into the gas delivery pipe 201 through the gas inlet valve port 151b, forming a closed internal circulation flow of the gas to be tested. Then, the detecting element 40 is used to measure the content of the judgment factor in the gas to be tested. In FIG. 9b, the pipes filled with dot patterns represent the gas, and the dashed arrows represent the gas flow direction.

FIG. 9c is an explanatory diagram of the second type of operation of the configuration shown in FIG. 9a, further revealing the execution mode of Step S11 shown in FIG. 7 for filling gas into the compartment space 14.

As shown in FIG. 9c, connect the said disk-shaped connectors 21a, 21b at both ends of the gas delivery pipe 201 to the gas inlet valve ports 151a, 151b of the FOUP 10, so that the gas loop 20 is connected to the compartment space 14 (i.e., execute Step S13). At this time, the fourth switch 54 and the fifth switch 55 remain closed (off), and the remaining first switch 51, second switch 52, third switch 53, and sixth switch 56 are all opened (on), so as to guide the filling gas (such as nitrogen with a concentration of 99.99%) through the gas inlet manifold pipe 202 into the compartment space 14 through the gas delivery pipe 201 and the disk-shaped connector 21a for pressure accumulation. The filling gas accumulated in the compartment space 14 can also flow back into the gas delivery pipe 201 through the disk-shaped connector 21b. During this period, the gas driver 30 can agitate the gas as appropriate to fully fill the filling gas into the gas delivery pipe 201, the communicating pipe 205, and the compartment space 14 for pressure accumulation to form the gas to be tested. However, when the pressure of the filling gas guided from the gas supply pipeline by the gas inlet manifold pipe 202 is very sufficient, the agitation of the gas driver 30 in Step S11 may not be necessary.

Accordingly, before filling the gas, if the original gas in the compartment space 14 (taking air as an example) is inconsistent with the filling gas to be filled (taking nitrogen with a concentration of 99.99% as an example), the filling pressure of nitrogen can be made greater than the internal pressure of the air in the compartment space 14, and they are mixed with each other to form, for example, nitrogen with a concentration of 80%, which is used as the gas to be tested for subsequent air-tightness measurement. In addition, before filling the filling gas, if the original gas in the compartment space 14 (such as nitrogen) is consistent with the filling gas to be filled (such as nitrogen), regardless of whether the nitrogen concentrations are the same or not, a specific concentration of nitrogen can be obtained after filling and mixing, which is used as the gas to be tested for subsequent air-tightness measurement. Also, before filling the gas, if the compartment space 14 is in a vacuum state and there is no gas, the negative-pressure environment in the compartment space 14 can be transformed into a positive-pressure environment by the filling gas (taking nitrogen with a concentration of 99.99% as an example), and it can be ensured that the concentration of the filled nitrogen still remains 99.99%, which is used as the gas to be tested for subsequent air-tightness measurement.

Further, as shown in FIG. 9c, when the pressure of the gas to be tested accumulated in the compartment space 14 exceeds a saturated-pressure state, the pressure generated by the gas to be tested can push open the two gas outlet valve ports 152a, 152b, and then the excess gas to be tested is discharged out of the compartment space 14. In addition, FIG. 9c also reveals that the excess gas to be tested flowing back into the gas delivery pipe 201 through the disk-shaped connector 21a can also be discharged outward through the discharge pipe 204 via the opened (on) sixth switch 56, so that the gas accumulated and integrated in the gas delivery pipe 201 and the communicating pipe 205 can be maintained in the same saturated-pressure state with the compartment space 14. In FIGS. 9b and 9c, the pipes filled with dot patterns represent that the gas has been filled, and the dashed arrows represent the filling and flow-guiding directions of the gas.

Specifically, if the concentration of the gas to be tested (such as nitrogen) accumulated in the compartment space 14 is reduced due to the mixing with the original gas (such as air) in the compartment space 14, during the process of filling the filling gas, the saturated-pressure discharge can be carried out through the gas outlet valve ports 152a, 152b, thereby increasing the concentration of the gas to be tested (such as nitrogen) accumulated in the compartment space 14. It is known that the higher the concentration of the gas to be tested used in the internal circulation, the more accurate the air-tightness detection of the FOUP can be.

Also, the two paired gas outlet valve ports 152a, 152b and the discharge pipe 204 can be respectively connected to a gas recovery pipe (not shown in the figure) to collect the excess gas. During this process, substances that can affect cleanliness and dryness (such as water molecules or other dirt or particles) can be carried away from at least one of the gas outlet valve ports 152a, 152b and the discharge pipe 204 to leave the compartment space 14, so as to improve the cleanliness and dryness of the compartment space 14.

Then, please refer back to FIG. 9b. As illustrated, after Step S11 shown in FIG. 9c, continue to execute Step S20 and Step S30 shown in FIG. 7, which are in the same mode as shown in FIG. 2.

FIG. 9d is an explanatory diagram of the third type of operation of the configuration shown in FIG. 9a, further revealing the implementation mode of Step S12 in FIG. 8 to fill gas into the gas loop.

As shown in FIG. 9d, the disk-shaped connectors 21a, 21b at both ends of the gas delivery pipe 201 have not yet been connected to the gas inlet valve ports 151a, 151b of the FOUP 10. At this time, all first switch 51 to sixth switch 56 are opened (on), and high-concentration filling gas is guided into the gas delivery pipe 201 and communicating pipe 205 via the gas inlet manifold pipe 202, enabling rapid establishment of high concentration and saturated pressure of the filling gas within the gas loop 20. Excess filling gas can be discharged to the external environment through the disk-shaped connectors 21a, 21b and the discharge pipe 204.

Subsequently, please refer to FIG. 9b again. In the operation shown in FIG. 8, once the Step S12 shown in FIG. 9d for filling gas into the gas loop is completed, continue to execute Step 13 to connect the gas loop to the compartment space. After completion of Step S13, continue to execute Step S20 and Step S30, which are the same as shown in FIG. 2.

Additionally, to implement the aforementioned detection method, please continue to refer to FIG. 10a, which discloses a schematic diagram of the configuration of the second-type measuring device illustrating the design of the device to execute the measurement technique shown in FIG. 5, particularly including the implementation details of Step 10 for constructing the gas loop.

As shown in FIG. 10a, the measuring device contains the gas delivery pipe 231 used for serial connection with the gas driver 30 and the detecting element 40. The solid gas delivery pipe 231 in FIG. 10a constitute the gas loop 23 shown in FIG. 5. The implementation in FIG. 10a differs from FIG. 9a as follows:

Regardless of whether the two (or one) disk-shaped connectors 21 have protruding nozzles 211, they are connected to one end of the gas delivery pipe 231 to correspond with the two (or one) gas inlet valve ports 151a, 151b on the shell 11 of the FOUP 10 during measurement. Meanwhile, the two (or one) disk-shaped connectors 22 without protruding nozzles 211 are installed at the other end of the gas delivery pipe 231 to correspond with the two (or one) gas outlet valve ports 152a, 152b on the shell 11 of the FOUP 10 during measurement. This configuration allows the detecting element 40 to be positioned between the gas driver 30 and any of the gas inlet valve ports 151a, 151b via the gas delivery pipe 231.

The gas delivery pipe 231 between the gas inlet valve ports 151a, 151b and the gas outlet valve ports 152a, 152b is branched at intervals to connect a gas inlet manifold pipe 232 linked to a gas supply source, a gas outlet manifold pipe 233, and a discharge pipe 234. Additionally, a communicating pipe 235 may be connected in parallel form between the gas driver 30 and the gas delivery pipes 231 on both sides of the detecting element 40.

Further, multiple switches 61~67 composed of solenoid valves or other electric or manual valves are arranged at intervals on the gas delivery pipe 231. As shown in FIG. 10a, the switches may include first switch 61 serially connected to the gas inlet manifold pipe 232, second switch 62 serially connected to the gas outlet manifold pipe 233, third switch 63 serially connected on the inlet end of the gas delivery pipe 231 adjacent to the gas inlet valve ports 151a, 151b, fourth switch 64 serially connected on the gas delivery pipe 231 between the gas outlet valve ports 152a, 152b and the gas driver 30, fifth switch 65 serially connected on the gas delivery pipe 231 between the detecting element 40 and third switch 63, sixth switch 66 serially connected on the communicating pipe 235, and seventh switch 67 serially connected on the discharge pipe 234. As shown in FIG. 10a, all switches 61~67 are in a closed (off) standby state. The rest of the implementation in FIG. 10a is substantially identical to FIG. 9a.

FIG. 10b is an explanatory diagram of the first type of operation of the configuration shown in FIG. 10a, further revealing the implementation modes of Step S20 to Step S30 shown in FIG. 2.

As shown in FIG. 10b, the gas loop 23 constructed in FIG. 10a can respectively connect to the gas inlet valve ports 151a, 151b and the gas outlet valve ports 152a, 152b of the FOUP 10 via the disk-shaped connectors 21, 22 at both ends of the gas delivery pipe 231. Subsequently, the third switch 63, fourth switch 64, and fifth switch 65 are opened (on), while the first switch 61, second switch 62, sixth switch 66, and seventh switch 67 remain closed (off). Now, the original gas within the gas delivery pipe 231 can be driven by the gas driver 30 into the compartment space 14 through the gas inlet valve ports 151a, 151b, mixed with the original gas in the compartment space 14, and then discharged back into the gas delivery pipe 231 via the gas outlet valve ports 152a, 152b, forming a closed-loop circulation of the gas to be measured. Then, the detecting element 40 is used to measure the judgement factor contained in the gas to be measured. In FIG. 10b, the pipes filled with dot patterns represent original gas, while dashed arrows indicate the flow direction of the measured gas.

FIG. 10c is an explanatory diagram of the second type of operation of the configuration shown in FIG. 10a, further revealing the implementation mode of Step S11 shown in FIG. 7 to fill gas into the compartment space 14.

FIG. 10c shows the implementation mode of executing Step 11 shown in FIG. 9c to fill gas into the compartment space 14 according to the connection mode of FIG. 10b. FIG. 10c differs from FIG. 9c in that, the fifth switch 65 is closed (off), and the rest first switch 61, second switch 62, third switch 63, fourth switch 64, sixth switch 66 and seventh switch 67 are opened (on), so that the original gas inside the gas loop 23 can enter the compartment space 14 via the two-directional paired disk-shaped connectors 21, 22 on the gas delivery pipe 231 to become the gas to be measured to facilitate subsequent execution of the above-mentioned Step S20 and Step S30.

FIG. 10d is an explanatory diagram of the third type of operation of the configuration shown in FIG. 10a, further revealing the implementation mode of Step S12 shown in FIG. 8 to fill gas into the gas loop 23.

As shown in FIG. 10d, the disk-shaped connectors 21, 22 at both ends of the gas delivery pipe 231 have not yet been connected to the gas inlet valve ports 151a, 151b and gas outlet valve ports 152a, 152b of the FOUP 10. At this time, all first switch 61 to seventh switch 67 are opened (on), and high-concentration filling gas is guided into the gas delivery pipe 231 and communicating pipe 235 via the gas inlet manifold pipe 232, enabling rapid establishment of high concentration and saturated pressure of the filling gas within the gas loop 23. Excess filling gas can be discharged to the external environment through the disk-shaped connectors 21, 22, gas outlet manifold pipe 233, and discharge pipe 234.

Then, please refer to FIG. 10b. In the operation shown in FIG. 8, once Step S12 (filling gas into the gas loo) shown in FIG. 10d is completed, continue to execute Step S13 (connecting the gas loop to the compartment space), and after completion of Step S13, continue to execute Step S20 and Step S30 as shown in FIG. 2.

Further, regarding the implementation mode of humidity detection of the present invention, reference can be made to the gas internal circulation mode shown in FIG. 9b and FIG. 10b. By using a moisture detector as the detecting element 40, the humidity detection described in the detection method can be carried out.

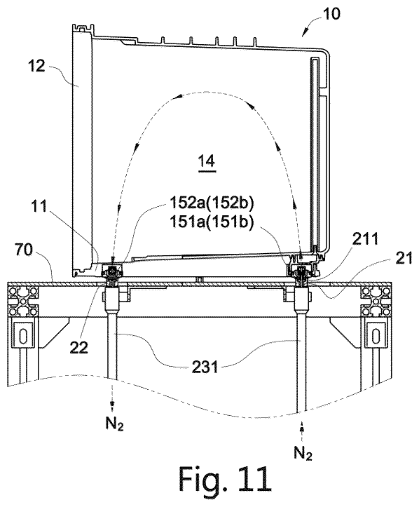

Further, please refer to FIG. 11, which discloses that the measuring device shown in FIG. 10a can be constructed on a platform 70 for placing the FOUP 10. The platform 70 can be a load port or a platform on other working machines, so that the disk-shaped connector 21 with a protruding nozzle 211 and the disk-shaped connector 22 without a protruding nozzle 211 are both prominent on the platform 70 and are respectively connected to the gas delivery pipe 231. In addition, all the components connected via the gas delivery pipe 231 in the above implementation can be arranged inside the body of the platform 70. Specifically, the platform 70 can be used for the aforementioned Step S13 (connecting the gas loops 20, 23 to the compartment space 14). That is, once the FOUP 10 is placed, the gas inlet valve ports 151a, 151b on the shell 11 of the FOUP 10 can be connected to the disk-shaped connector 21 with a protruding nozzle 211, and the protruding nozzle 211 can push open the one-way check valve in the disk-shaped connector 21. And the gas outlet valve ports 152a, 152b on the shell 11 can be connected to the disk-shaped connector 22 without a protruding nozzle 211, so as to communicate with the gas delivery pipe and to guide the gas into and out of the compartment space 14. In addition, the implementation components shown in FIG. 9a can also be assembled and configured with the platform for placing the FOUP 10 to facilitate establishment of the gas loop and the aforementioned gas measuring process.

As described above, the implementation details of the above-mentioned detection device of the present invention are sufficient for specific implementation of the aforementioned detection method of the invention. Moreover, both the measuring method and device possess the capability to detect the air-tightness, gas concentration, and humidity inside the compartment space of the FOUP. Compared to prior art, this invention obviously demonstrates industrial applicability and technical advancement

Although the invention has been explained in relation to its preferred embodiment, it is to be understood that many other possible modifications and variations can be made without departing from the spirit and scope of the invention as hereinafter claimed.

1. A method for measuring gas inside a FOUP, used for measuring the gas within a compartment space of the FOUP, wherein the compartment space is formed within a shell and sealed by a door closing the shell, and the shell comprises at least two valve ports to control the time of gas communication between the compartment space and the external environment, the method comprises:
constructing a closed gas loop, which connects to the compartment space via the at least two valve ports; driving the gas to generate internal circulation flow between the compartment space and the gas loop; and measuring the content of a judgment factor in the circulating gas to detect the air-tightness of the compartment space and the gas concentration.

2. The method for measuring gas inside a FOUP defined in claim 1, wherein prior to driving the gas to generate internal circulation flow, the gas is first filled into the compartment space via the gas loop.

3. The method for measuring gas inside a FOUP defined in claim 1, wherein prior to connecting the gas loop to the compartment space, the gas is first filled into the gas loop.

4. The method for measuring gas inside a FOUP defined in claim 1, wherein the gas is nitrogen, and the judgment factor is the nitrogen content or oxygen content in the nitrogen.

5. The method for measuring gas inside a FOUP defined in claim 1, wherein the gas is air, and the judgment factor is the oxygen content in the air.

6. The method for measuring gas inside a FOUP defined in claim 1, wherein the gas is an inert gas, and the judgment factor is the content of oxygen, helium, neon, argon, krypton, xenon, or radon.

7. The method for measuring gas inside a FOUP defined in claim 1, which further comprises detecting humidity within the compartment space, wherein the judgment factor is the water molecule content in the gas.

8. A device for measuring gas inside a FOUP, used for measuring the gas within a compartment space of the FOUP, wherein, the compartment space is formed within a shell and sealed by a door closing the shell, and the shell comprises at least two valve ports to control the time of gas communication between the compartment space and the external environment, the device comprises:
a gas delivery pipe, connected between the at least two valve ports and communicating with the compartment space, said gas delivery pipe being used to guide gas into the compartment space and form a closed gas loop;
a gas driver, serially connected to the gas delivery pipe, and used to drive the gas to generate internal circulating flow between the compartment space and the gas delivery pipe; and
a detecting element, serially connected to the gas delivery pipe, and positioned between the gas driver and one of the at least two valve ports, used to measure the content of a judgment factor in the circulating gas.

9. The device for measuring gas inside a FOUP defined in claim 8, wherein the at least two valve ports include two gas inlet valve ports, the gas delivery pipe has disk-shaped connectors at both ends, and at least one of the two disk-shaped connectors comprises a protruding nozzle, the gas delivery pipe seals the gas inlet valve ports via the disk-shaped connectors, and is inserted into at least one of the gas inlet valve ports via the protruding nozzle to establish communication with the compartment space.

10. The device for measuring gas inside a FOUP defined in claim 8, wherein the at least two valve ports include at least one gas inlet valve port and at least one gas outlet valve port.

11. The device for measuring gas inside a FOUP defined in claim 10, wherein the gas delivery pipe has disk-shaped connectors at both ends, the gas delivery pipe seals at least one gas inlet valve port and at least one gas outlet valve port via the disk-shaped connectors to establish communication with the compartment space.

12. The device for measuring gas inside a FOUP defined in claim 11, wherein at least one of the disk-shaped connectors comprises a protruding nozzle, and the gas delivery pipe is inserted into at least one gas inlet valve port via the protruding nozzle.

13. The device for measuring gas inside a FOUP defined in claim 9, which is constructed on a platform for placing the FOUP, with the disk-shaped connectors protruding from the platform to connect to the valve ports when the FOUP is placed.

14. The device for measuring gas inside a FOUP defined in claim 8, wherein the gas delivery pipe further extends to connect with at least one gas inlet manifold pipe linked to a gas supply source and at least one gas outlet manifold pipe for gas discharge, and a plurality of switches are configured on the gas delivery pipe, the gas inlet manifold pipe, and the gas outlet manifold pipe to control the time for filling, directing, and discharging of the gas.

15. The device for measuring gas inside a FOUP defined in claim 14, wherein the plurality of switches are solenoid valves.

16. The device for measuring gas inside a FOUP defined in claim 8, wherein the gas driver is a pump or blower.

17. The device for measuring gas inside a FOUP defined in claim 8, wherein the gas is nitrogen, the judgment factor is the oxygen or nitrogen content in the nitrogen, and the detecting element is an oxygen sensor or a gas monitoring instrument for detecting nitrogen content.

18. The device for measuring gas inside a FOUP defined in claim 8, wherein the gas is an inert gas, the judgment factor is the content of oxygen, helium, neon, argon, krypton, xenon, or radon, and the detecting element is an oxygen sensor or a gas monitoring instrument for detecting the content of oxygen, helium, neon, argon, krypton, xenon, or radon.

19. The device for measuring gas inside a FOUP defined in claim 8, wherein the gas is air, the judgment factor is the oxygen content in the air, and the detecting element is an oxygen sensor.

20. The device for measuring gas inside a FOUP defined in claim 8, which is further used for detecting humidity inside the compartment space, where the judgment factor is the water molecule content in the gas, and the detecting element is a moisture sensor.
